(19) United States
(12) Patent Application Publication
(10) Pub. No.: US 2025/0311585 A1
(43) Pub. Date: Oct. 2, 2025

(54) PATTERNING OVERHANG AS TOUCH ELECTRODES

(71) Applicant: Applied Materials, Inc., Santa Clara, CA (US)

(72) Inventors: Chung-Chia CHEN, Hsinchu City (TW); Yu-Hsin LIN, Zhubei City (TW); Ji Young CHOUNG, Hwaseong-si (KR); Sheng-Wen WANG, Tainan City (TW); Jungmin LEE, Santa Clara, CA (US)

(21) Appl. No.: 19/097,559

(22) Filed: Apr. 1, 2025

Related U.S. Application Data
(60) Provisional application No. 63/573,145, filed on Apr. 2, 2024.

(51) Int. Cl. H10K 59/40; H10K 59/122; H10K 59/80

(52) U.S. Cl. CPC H10K 59/40; H10K 59/122; H10K 59/80521; H10K 59/80522; H10K 59/873

(57) ABSTRACT

Devices with sub-pixel circuits and methods of forming sub-pixel circuits that may be utilized in a display such as an organic light-emitting diode (OLED) display. The device includes a substrate, a plurality of overhang structures disposed over the substrate where the overhang structures include a first structure, a second structure. The device further includes a plurality of sub-pixels defined by the overhang structures where each sub-pixel includes an organic light emitting diode (OLED) material disposed between the overhang structures, a cathode disposed over the OLED material, and an encapsulation layer disposed over the cathode and the second structure over each of the overhang structures. The device further includes an intermediate layer disposed over the encapsulation layer and a global passivation layer disposed over the intermediate layer. The device further includes a first touch electrode disposed over the second structure and a second touch electrode disposed over the global passivation layer.

### CROSS-REFERENCE TO RELATED APPLICATION

This application claims the benefit of and priority to U.S. Provisional Patent Application No. 63/573,145, filed Apr. 2, 2024, which is incorporated by reference herein in its entirety.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing a higher resolution.

Currently, OLED devices that include a touch screen panel require multiple layers of film and an intensive process to manufacture. Accordingly, what is needed in that art is a thinner OLED device that include a touch screen panel and a simplified process to manufacture the devices.

### SUMMARY

In one embodiment, a device is disclosed. The device includes a substrate, a plurality of overhang structures disposed over the substrate where the overhang structures include a first structure, a second structure, and adjacent overhangs where each overhang defined by an overhang extension of the second structure extending laterally past an upper surface of the first structure. The device further includes a plurality of sub-pixels defined by the overhang structures where each sub-pixel includes an organic light emitting diode (OLED) material disposed between the overhang structures, a cathode disposed over the OLED material, and an encapsulation layer disposed over the cathode and the second structure over each of the overhang structures. The device further includes a first touch electrode disposed over the second structure and a second touch electrode disposed over the overhang structures.

In another embodiment, a device is disclosed. The device includes a substrate, a plurality of overhang structures disposed over the substrate where the overhang structures include a first structure, a second structure, and adjacent overhangs where each overhang defined by an overhang extension of the second structure extending laterally past an upper surface of the first structure. The device further includes a plurality of sub-pixels defined by the overhang structures where each sub-pixel includes an organic light emitting diode (OLED) material disposed between the overhang structures, a cathode disposed over the OLED material, and an encapsulation layer disposed over the cathode and the second structure over each of the overhang structures. The device further includes an intermediate layer disposed over the encapsulation layer and a global passivation layer disposed over the intermediate layer. The device further includes a first touch electrode disposed over the second structure and a second touch electrode disposed over the global passivation layer.

In yet another embodiment, a device is disclosed. The device includes a substrate, a plurality of overhang structures disposed over the substrate where the overhang structures include a first structure, a second structure including conductive material, and adjacent overhangs where each overhang defined by an overhang extension of the second structure extending laterally past an upper surface of the first structure. The device further includes a plurality of sub-pixels defined by the overhang structures where each sub-pixel includes an organic light emitting diode (OLED) material disposed between the overhang structures, a cathode disposed over the OLED material, an encapsulation layer disposed over the cathode and the second structure over each of the overhang structures, an intermediate layer, and a global passivation layer. The device further includes a touch electrode disposed over the global passivation layer that is disposed over the sub-pixels.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a first sub-pixel circuit, according to embodiments.

FIG. 1B is a schematic, cross-sectional view of an overhang structure of the first sub-pixel circuit, according to embodiments.

FIG. 1C is a schematic, cross-sectional view of a second sub-pixel circuit, according to embodiments.

FIG. 1D is a schematic, cross-sectional view of an overhang structure of the second sub-pixel circuit, according to embodiments.

FIG. 2A is a schematic, top-view of a sub-pixel circuit having a line-type architecture, according to embodiments.

FIG. 2B is a schematic, cross-sectional view of a sub-pixel circuit having a line-type architecture at section line B′-B,′ according to embodiments.

FIG. 3 is schematic top view of a sub-pixel circuit having a dot-type architecture, according to embodiments.

FIG. 4A is cross-sectional view of an overhang structure of the third sub-pixel circuit, according to embodiments.

FIG. 4B is a cross-sectional view of an overhang structure of a fourth sub-pixel circuit, according to embodiments.

FIG. 5 is cross-sectional view of an overhang structure of the fifth sub-pixel circuit, according to embodiments.

FIG. 6 is cross-sectional view of an overhang structure of the sixth sub-pixel circuit, according to embodiments.

FIG. 7 is a flow diagram of a method for forming a sub-pixel, according to embodiments.

FIGS. 8A-8D are schematic, cross-sectional views of a substrate during a method of forming a sub-pixel, according to embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. In various embodiments, the sub-pixels employ advanced overhang structures to improve functionality of the display.

Each of the embodiments described herein of the sub-pixel circuit include a plurality of sub-pixels with each of the sub-pixels defined by adjacent overhang structures that are permanent to the sub-pixel circuit. While the Figures depict two sub-pixels with each sub-pixel defined by adjacent overhang structures, the sub-pixel circuit of the embodiments described herein include a plurality of sub-pixels, such as two or more sub-pixels. Each sub-pixel has OLED materials configured to emit a white, red, green, blue or other color light when energized. E.g., the OLED materials of a first sub-pixel emits a red light when energized, the OLED materials of a second sub-pixel emits a green light when energized, and the OLED materials of a third sub-pixel emits a blue light when energized.

The overhangs are permanent to the sub-pixel circuit and include at least a second structure disposed over a first structure. The adjacent overhang structures defining each sub-pixel of the sub-pixel circuit of the display provide for formation of the sub-pixel circuit using evaporation deposition and provide for the overhang structures to remain in place after the sub-pixel circuit is formed. Evaporation deposition is utilized for deposition of OLED materials (including a hole injection layer (HIL), a hole transport layer (HTL), an emissive layer (EML), and an electron transport layer (ETL)) and a cathode. In some instances, an encapsulation layer may be disposed via evaporation deposition. In embodiments including one or more capping layers, the capping layers are disposed between the cathode and the encapsulation layer. The encapsulation layer of a respective sub-pixel is disposed over the cathode. The sub-pixel further includes a touch screen panel (TSP). The TSP includes a touch-x axis electrode (e.g. a first electrode), a dielectric layer, and a touch-Y axis electrode (e.g. a second electrode). In some embodiments, the dielectric layer is the encapsulation layer. In one or more embodiments, the device further includes an intermediate layer and/or a global passivation layer. The intermediate layer and/or the global passivation layer are planarized. The touch-x axis electrode is disposed over the overhang structure. The encapsulation layer is disposed over the sub-pixel. The touch-y axis electrode is disposed over the dielectric layer. In one or more embodiments, the touch-y electrodes are disposed over the intermediate layer and/or the global passivation layer. Alternatively, the TSP includes an overhang structure that is a first electrode, a dielectric layer, and a touch-y axis electrode. This enables for a TSP to be integrated into the OLED display.

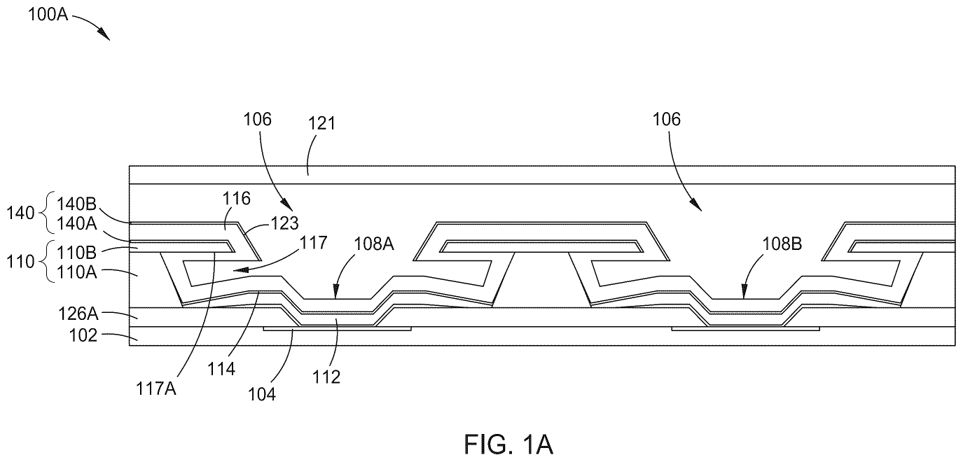

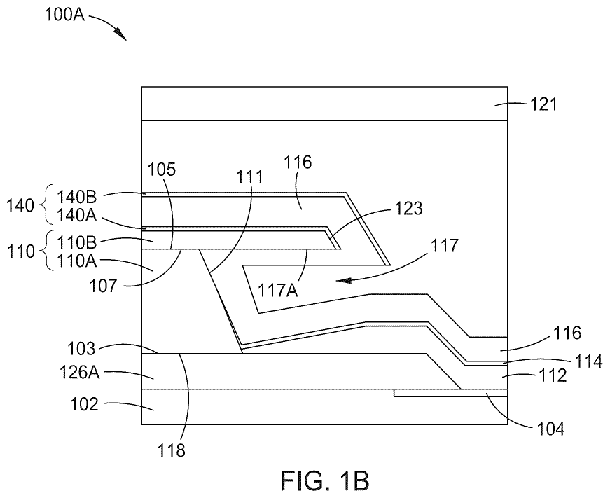

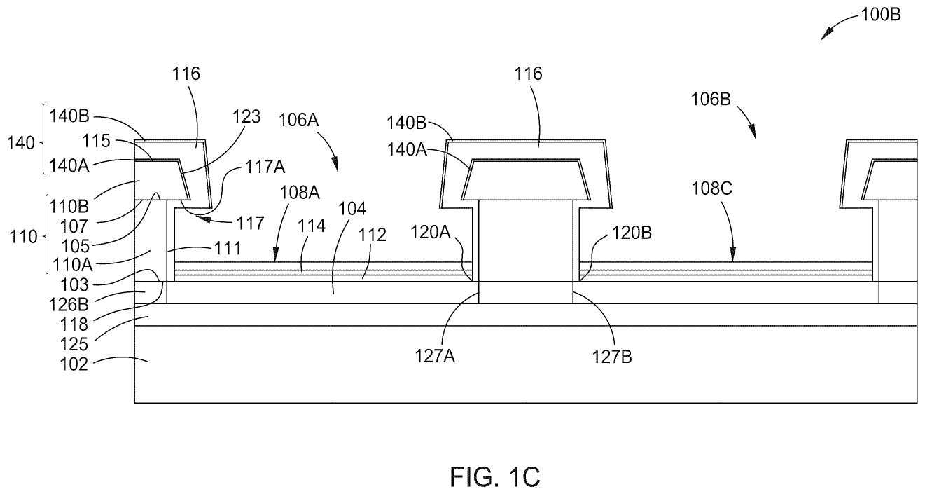

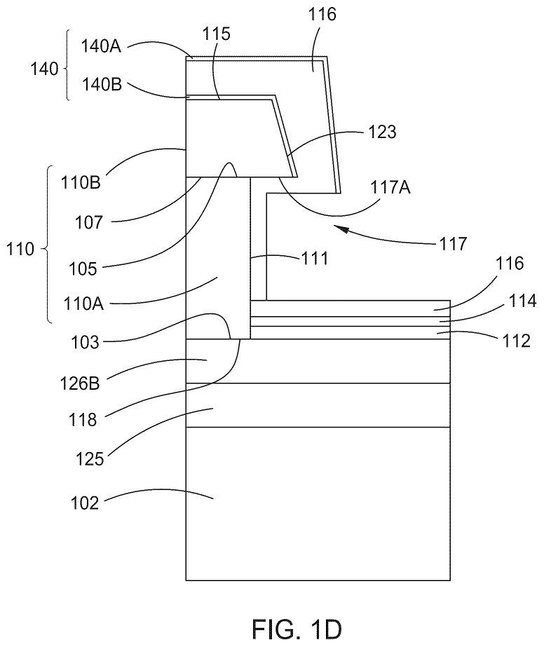

FIG. 1A is a schematic, cross-sectional view of a first sub-pixel circuit 100A. FIG. 1B is a schematic, cross-sectional view of an overhang structure 110 of the first sub-pixel circuit 100A. The first sub-pixel circuit 100A includes a substrate 102. Metal-containing layers 104 may be patterned on the substrate 102 and are defined by adjacent pixel structures (PS) 126A disposed on the substrate 102. In one embodiment, the PS 126A are disposed on the substrate 102. In one embodiment, the metal-containing layers 104 are pre-patterned on the substrate 102. E.g., the substrate 102 is pre-patterned with metal-containing layers 104 of indium tin oxide (ITO). The metal-containing layers 104 are configured to operate as anodes of respective sub-pixels. In one embodiment, the metal-containing layer 104 is a layer stack of a first transparent conductive oxide (TCO) layer, a second metal-containing layer disposed on the first TCO layer, and a third TCO layer disposed on the second metal-containing layer. The metal-containing layers 104 include, but are not limited to, chromium, titanium, gold, silver, copper, aluminum, ITO, a combination thereof, or other suitably conductive materials.

The plurality of PS 126A are disposed over the substrate 102. The PS 126A include one of an organic material, an organic material with an inorganic coating disposed thereover, or an inorganic material. The organic material of the PS 126A includes, but is not limited to, polyimides. The inorganic material of the PS 126A includes, but is not limited to, silicon oxide (SiO₂), silicon nitride (Si₃N₄), silicon oxynitride (Si₂N₂O), magnesium fluoride (MgF₂), or combinations thereof. Adjacent PS 126A define a respective sub-pixel and expose the anode (i.e., metal-containing layer 104) of the first sub-pixel circuit 100A.

The first sub-pixel circuit 100A has a plurality of sub-pixels 106 including at least a first sub-pixel 108A and a second sub-pixel 108B. While the Figures depict the first sub-pixel 108A and the second sub-pixel 108B, the first sub-pixel circuit 100A of the embodiments described herein may include two or more sub-pixels 106, such as a third and a fourth sub-pixel. Each sub-pixel 106 has OLED materials configured to emit a white, red, green, blue or other color light when energized. E.g., the OLED materials of the first sub-pixel 108A emits a red light when energized, the OLED materials of the second sub-pixel 108B emits a green light when energized, the OLED materials of a third sub-pixel emits a blue light when energized, and the OLED materials of a fourth sub-pixel emits another color light when energized.

Each sub-pixel 106 includes an overhang structure 110. The overhang structures 110 are permanent to the first sub-pixel circuit 100A. The overhang structures 110 further define each sub-pixel 106 of the first sub-pixel circuit 100A. Each overhang structure 110 includes adjacent first overhangs 117. The adjacent first overhangs are defined by a overhang extension 117A (as shown in Figure. 1B) of a second structure 110B extending laterally past an upper surface 105 of a first structure 110A. The first structure 110A is disposed over an upper surface 103 (as shown in Figure. 1B) of the plurality of adjacent PS 126A.

The second structure 110B includes a conductive inorganic material and the first structure 110A includes a conductive inorganic material. The conductive materials of the first structure 110A include aluminum (Al), aluminum neodymium (AlNd), molybdenum (Mo), molybdenum tungsten (MoW), copper (Cu), or combinations thereof. In one embodiment, the first structure 110A includes a metal containing material. In one example, the metal-containing material is a transparent conductive oxide (TCO) material. The TCO material includes, but is not limited to, indium zinc oxide (IZO), indium tin oxide (ITO), indium gallium zinc oxide (IGZO), or combinations thereof. In another embodiment, the first structure 110A includes a conductive inorganic material and the second structure 110B include a nonconductive inorganic material. The inorganic materials of the second structure 110B include silicon nitride (Si₃N₄), silicon oxide (SiO₂), silicon oxynitride (Si₂N₂O), or combinations thereof. In one or more embodiments, the second structure 110B includes a conductive material and the first structure 110A includes a nonconductive material. The overhang structures 110 are able to remain in place, i.e., are permanent.

Adjacent first overhangs 117 are defined by an overhang extension 117A. At least a bottom surface 107 of the second structure 110B is wider than the upper surface 105 of a first structure 110A to form the overhang extension 117A. The overhang extension 117A of the second structure 110B forms the overhang 117 and enables the second structure 110B to shadow the first structure 110A. The shadowing of the overhang 117 provides for evaporation deposition of OLED materials 112 and a cathode 114. The OLED materials 112 may include one or more of a HIL, a HTL, an EML, and an ETL. The OLED material is disposed over and in contact with the metal-containing layer 104. The OLED material 112 is disposed under adjacent first overhang 117. The cathode 114 includes a conductive material, such as a metal. E.g., the cathode 114 includes, but is not limited to, silver, magnesium, chromium, titanium, aluminum, ITO, or a combination thereof. The cathode 114 is disposed over the OLED material 112 and a sidewall of the first structure 110A of the overhang structures 110. In other embodiments, the cathode 114 has an endpoint before the first structure 110A. I.e., the cathode 114 does not contact the sidewall 111 of the first structure 110A.

Each sub-pixel 106 includes an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of each of the overhangs 117. The encapsulation layer 116 includes the nonconductive inorganic material, such as the silicon-containing material. The silicon-containing material may include Si₃N₄ containing materials. In another embodiment the encapsulation layer 116 includes dielectric material.

In embodiments including one or more capping layers, the capping layers are disposed between the cathode 114 and the encapsulation layer 116. E.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition. In another embodiment, the first sub-pixel circuit 100A further includes at least a global passivation layer 120 disposed over the overhang structure 110 and the encapsulation layer 116. In yet another embodiment, the sub-pixel includes an intermediate layer 121 disposed over the overhang structures 110 of each of the sub-pixels 106, and disposed between the encapsulation layer 116 and the global passivation layer 120.

A touch electrode 140 is used to provide touch screen capabilities to an OLED device. The touch electrode 140 includes a touch-x axis electrode 140A (e.g. a first electrode), a dielectric layer, and a touch-y axis electrode 140B (e.g. a second electrode). In one or more embodiments, the touch-x axis electrodes and/or the touch-y axis electrodes include a TCO material such as ITO, a metal material (e.g., Cu or an Ag metal mesh), or nanowires (e.g., Ag nanowires or carbon (C) nanowires). The touch-x axis electrode 140A is disposed over the second structure 110B. The second structure 110B includes a nonconductive material. In certain embodiments, the dielectric layer of the touch electrode 140 is the encapsulation layer 116 of the sub-pixel circuit (e.g., the first sub-pixel circuit 100A). The encapsulation layer 116 includes a dielectric material. The dielectric material includes SiNₓ, SiOₓ, SiON or Al₂O₃. The touch-y axis electrode 140B is disposed over the encapsulation layer 116. In other embodiments, the overhang structure 110 is the touch-x axis electrode 140A (e.g. a first electrode). In this embodiment, the first structure 110A includes a conductive or nonconductive material and the second structure 110B includes a conductive material. The dielectric layer of the touch electrode 140 is the encapsulation layer 116. A touch-Y axis electrode is disposed over the encapsulation layer 116. In another embodiment, the touch-y axis electrode 140B is disposed over a global passivation layer 120.

In some embodiments, as shown in FIG. 1A, the first structure 110A includes a nonconductive material. The OLED material 112 and the cathode 114 are disposed on the sidewall 111 of the first structure 110A. The nonconductive material of the first structure 110A reduces or prevents interference between the cathode 114 and the touch electrodes 140. In other embodiments, the OLED material 112 has an endpoint before the first structure 110A. E.g., the OLED material 112 does not contact the sidewall 111 of the first structure 110A. The cathode 114 does contact the sidewall 111 of the first structure 110A. In another embodiment, the OLED material 112 has an endpoint before the first structure 110A. The cathode 114 has an endpoint before the first structure 110A. E.g., the cathode 114 does not contact the sidewall 111 of the first structure 110A. The integration of the touch electrodes 140 into the overhang structure 110 or the overhang structure 110 as a touch electrode 140 enables a simplified structure of a touch screen device and a reduction in thickness of a device utilizing a touch screen and an OLED device.

FIG. 1C is a schematic, cross-sectional view of a second sub-pixel circuit 100B. FIG. 1D is a schematic, cross-sectional view of an overhang structure 110 of a second sub-pixel circuit 100B. The second sub-pixel circuit 100B includes a substrate 102. A base layer 125 may be patterned over the substrate 102. The base layer 125 includes, but is not limited to, a CMOS layer. Metal-containing layers 104 (e.g., anodes) may be patterned on the base layer 125 and are defined by adjacent pixel structures (PS) 126B disposed on the substrate 102. In one embodiment, the metal-containing layer 104 are pre-patterned on the base layer 125. E.g., the base layer 125 is pre-patterned with metal-containing layer 104 of indium tin oxide (ITO). The metal-containing layer 104 may be disposed on the substrate 102. The metal-containing layer 104 is configured to operate as an anode of respective sub-pixels. In one embodiment, the metal-containing layer 104 is a layer stack of a first transparent conductive oxide (TCO) layer, a second metal-containing layer disposed on the first TCO layer, and a third TCO layer disposed on the second metal-containing layer. The metal-containing layer 104 include, but are not limited to, chromium, titanium, gold, silver, copper, aluminum, ITO, a combination thereof, or other suitably conductive materials.

The PS 126B are disposed over the substrate 102. The PS 126B may be disposed on the base layer 125. The PS 126B include one of an organic material, an organic material with an inorganic coating disposed thereover, or an inorganic material. The organic material of the PS 126B includes, but is not limited to, polyimides. The inorganic material of the PS 126B includes, but is not limited to, silicon oxide (SiO₂), silicon nitride (Si₃N₄), silicon oxynitride (Si₂N₂O), magnesium fluoride (MgF₂), or combinations thereof. Adjacent PS 126B define a respective sub-pixel and expose the metal-containing layer 104 of the respective second sub-pixel circuit 100B.

The second sub-pixel circuit 100B has a plurality of sub-pixel lines (e.g., first sub-pixel line 106A and second sub-pixel line 106B). The sub-pixel lines are adjacent to each other along the pixel plane. Each sub-pixel line includes at least two sub-pixels. E.g., the first sub-pixel line 106A includes a first sub-pixel 108A and a second sub-pixel (not shown) and the second sub-pixel line 106B includes a third sub-pixel 108C and a fourth sub-pixel (not shown). While FIG. 1A depicts the first sub-pixel line 106A and the second sub-pixel line 106B, the second sub-pixel circuit 100B of the embodiments described herein may include two or more sub-pixel lines, such as a third sub-pixel line and a fourth sub-pixel line. Each sub-pixel line has OLED materials configured to emit a white, red, green, blue or other color light when energized. E.g., the OLED materials of the first sub-pixel line 106A emits a red light when energized, the OLED materials of the second sub-pixel line 106B emits a green light when energized, the OLED materials of a third sub-pixel line emits a blue light when energized, and the OLED materials of a fourth sub-pixel emits another color light when energized. The OLED materials within a pixel line may be configured to emit the same color light when energized. E.g., the OLED materials of the first sub-pixel 108A and the second sub-pixel of the first sub-pixel line 106A emit a red light when energized and the OLED materials of the third sub-pixel 108C and the fourth sub-pixel of the second sub-pixel line 106B emit a green light when energized.

Each sub-pixel line includes adjacent overhang structures 110, with adjacent sub-pixel lines sharing the adjacent overhang structures 110. The overhang structures 110 are permanent to the second sub-pixel circuit 100B. The overhang structures 110 further define each sub-pixel line of the second sub-pixel circuit 100B. Each overhang structure 110 includes adjacent overhangs 117. The adjacent overhangs 117 are defined by an overhang extension 117A of a second structure 110B extending laterally past an upper surface 105 of a first structure 110A. The first structure 110A is disposed over an upper surface 103 of the PS 126B. A first endpoint 120A of a bottom surface 118 of the first structure 110A may extend to or past a first edge 127A of the PS 126B. A second endpoint 120B of the bottom surface of the first structure 110A may extend to or past a second edge 127B of the PS 126B.

The second structure 110B is disposed over the first structure 110A. The second structure 110B may be disposed on the upper surface 105 of the first structure 110A. The second structure 110B may also be disposed over an intermediate structure. The intermediate structure may be disposed over the upper surface 105 of the first structure 110A. The intermediate structure may be a seed layer or an adhesion layer. The seed layer functions as a current path for the second sub-pixel circuit 100B. The adhesion promotion layer improves adhesion between the first structure 110A and the second structure 110B. The adhesion layer may include a chromium (Cr) material.

In one embodiment, the second structure 110B includes a conductive inorganic material and the first structure 110A includes a conductive inorganic material. The conductive materials of the second structure 110B include a copper (Cu), chromium (Cr), aluminum (Al), aluminum neodymium (AlNd), molybdenum (Mo), molybdenum tungsten (MoW), titanium (Ti), transparent conductive oxide (TCO), or combinations thereof. The overhang structures 110 are able to remain in place, i.e., are permanent. In another embodiment, the first structure 110A includes a conductive inorganic material and the second structure 110B include a nonconductive inorganic material. The inorganic materials of the second structure 110B include silicon nitride (Si₃N₄), silicon oxide (SiO₂), silicon oxynitride (Si₂N₂O), or combinations thereof. In one or more embodiments, the first structure 110A includes a nonconductive material and the second structure 110B includes a conductive material.

Adjacent first overhangs 117 are defined by an overhang extension 117A. At least a bottom surface 107 of the second structure 110B is wider than the upper surface 105 of a first structure 110A to form the overhang extension 117A. The overhang extension 117A of the second structure 110B forms the overhang 117 and enables the second structure 110B to shadow the first structure 110A. The shadowing of the overhang 117 provides for evaporation deposition of OLED materials 112 and a cathode 114. The OLED materials 112 may include one or more of a HIL, a HTL, an EML, and an ETL. The OLED material is disposed over and in contact with the metal-containing layer 104. The OLED material 112 is disposed under adjacent first overhang 117. The cathode 114 includes a conductive material, such as a metal. E.g., the cathode 114 includes, but is not limited to, silver, magnesium, chromium, titanium, aluminum, ITO, or a combination thereof. In some embodiments, the cathode 114 is disposed over the OLED material 112 and a sidewall 123 of the second structure 110B of the overhang structures 110. In one embodiment, material of the cathode 114 is different from the material of the first structure 110A, the second structure 110B, and intermediate structure. In some embodiments, e.g., as shown in FIGS. 1C as applied to the second sub-pixel circuit 100B, the OLED material 112 and the cathode 114 are disposed over a sidewall 123 of the second structure 110B of the overhang structures 110 in the pixel plane. In other embodiments, the OLED material 112 and the cathode 114 are disposed over an upper surface 115 of the second structure 110B of the overhang structures 110 in the pixel plane. In still other embodiments, the OLED material 112 and the cathode 114 end on the sidewall 111 of the first structure 110A, i.e., are not disposed over the sidewall 123 of the second structure 110B in the pixel plane.

Each sub-pixel 106 includes an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of each of the overhangs 117 and along a sidewall 111 of each of the first structure 110A and the second structure 110B. The encapsulation layer 116 is disposed over the cathode 114. In some embodiments, the encapsulation layer 116 extends to contact the sidewall 111 of the first structure 110A. In the illustrated embodiments as shown in FIGS. 1C and 1D, the encapsulation layer 116 extends to contact the second structure 110B at an underside surface of the overhang extension 117A and the sidewall 123. In some embodiments, the encapsulation layer 116 ends at the sidewall 111 of the first structure 110A, e.g., is not disposed over the sidewall 123 of the second structure 110B, the underside surface of the overhang extension 117A. The encapsulation layer 116 includes the nonconductive inorganic material, such as the silicon-containing material. The silicon-containing material may include Si₃N₄ containing materials. In some embodiments the encapsulation layer 116 includes a dielectric material.

In embodiments including one or more capping layers, the capping layers are disposed between the cathode 114 and the encapsulation layer 116. E.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition. In another embodiment, the second sub-pixel circuit 100B further includes at least a global passivation layer disposed over the overhang structure 110 and the encapsulation layer 116. In yet another embodiment, the sub-pixel includes an intermediate layer 121 disposed over the overhang structures 110 of each of the sub-pixels 106, and disposed between the encapsulation layer 116 and the global passivation layer 120 (not pictured).

Each sub-pixel line has adjacent separation structures, with adjacent sub-pixels sharing the adjacent separation structures in the line plane. The separation structures are permanent to the second sub-pixel circuit 100B. The separation structures further define each sub-pixel of the sub-pixel line of the second sub-pixel circuit 100B. The separation structures are disposed over an upper surface 103 of the PS 126B.

A touch electrode 140 is used to provide touch screen capabilities to an OLED device. In one or more embodiments, a touch electrode 140 is integrated into the overhang structures 110. In one or more embodiments, the touch-x axis electrodes and/or the touch-y axis electrodes include a TCO material such as ITO, a metal material (e.g., Cu or an Ag metal mesh), or nanowires (e.g., Ag nanowires or carbon (C) nanowires). The touch electrode 140 includes a touch-x axis electrode 140A, a dielectric layer, and a touch-y axis electrode 140B. The touch-x axis electrode 140A is disposed over the second structure 110B. In other embodiments, the overhang structure 110 is the touch-x axis electrode 140A. In certain embodiments, the dielectric layer of the touch electrode 140 is the encapsulation layer 116 of the second sub-pixel circuit 100B. The encapsulation layer 116 includes a dielectric material. The touch-y axis electrode 140B is disposed over the encapsulation layer 116 over the second structure 110B. In this embodiment, the first structure 110A includes a nonconductive material. The OLED material 112 and the cathode 114 are disposed on the sidewall 111 of the first structure 110A. In other embodiments, the OLED material 112 has an endpoint before the first structure 110A. E.g., the OLED material 112 does not contact the sidewall 111 of the first structure 110A. The cathode 114 does contact the sidewall 111 of the first structure 110A. In another embodiment, the OLED material 112 has an endpoint before the first structure 110A. The cathode 114 has an endpoint before the first structure 110A. E.g., the cathode 114 does not contact the sidewall 111 of the first structure 110A. The nonconductive material of the first structure 110A reduces or prevents interference between the cathode 114 and the touch electrodes 140. In yet another embodiment, the touch-Y electrode may be disposed over the global passivation layer 120. The integration of the touch electrodes 140 into the overhang structure 110 enables a simplified structure of a touch screen device and a reduction in thickness of a device utilizing a touch screen and an OLED device.

The OLED material 112 is disposed over and in contact with the metal-containing layer 104 and the separation structure in the line plane. The cathode 114 is disposed over the OLED material 112 in the line plane. The encapsulation layer 116 is disposed over the cathode 114 in the line plane. The OLED material 112, the cathode 114, and the encapsulation layer 116 maintain continuity along the length of the line plane in order to apply current across each sub-pixel 106. In embodiments that include a touch electrode, as shown in FIG. 1D, the touch-x axis electrode 140A is disposed over the second structure 110B, an encapsulation layer 116, which includes a dielectric material is disposed over the line plane, and the touch-y axis electrode 140B is disposed over the encapsulation layer 116 over the overhang structures 110.

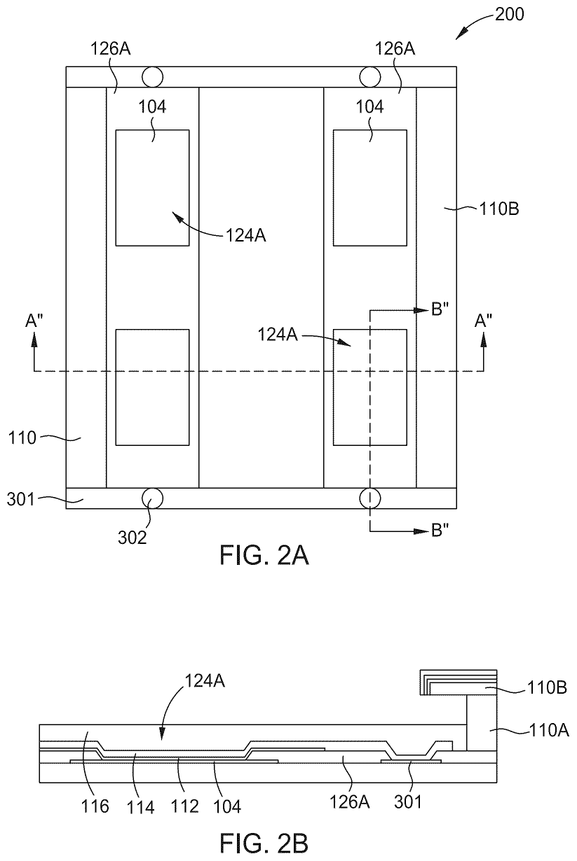

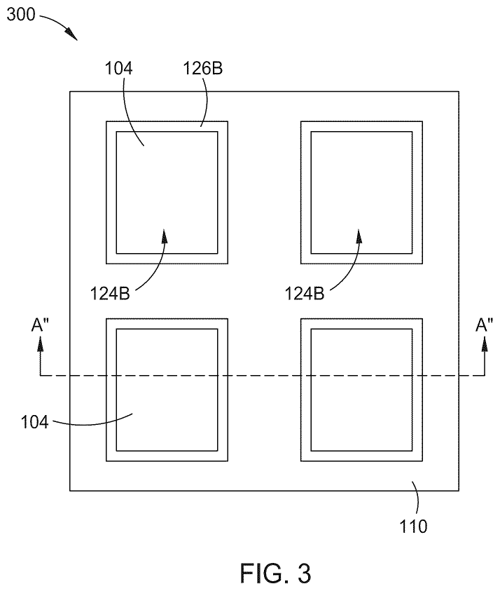

FIG. 2A is top view of first sub-pixel circuit 100A or a second sub-pixel circuit 100B having a line-type architecture 200. FIG. 2B shows a cross section along section line B′-B′ depicting a sub-pixel circuit. FIG. 3 is a top view of a first sub-pixel circuit 100A or a second sub-pixel circuit 100B having a dot-type architecture 300. In one or more embodiments, the line-type architecture 200 includes a plurality of pixel openings 124A from adjacent PS 126A. In one or more embodiments, the line-type architecture 200 includes a plurality of pixel openings 124A from adjacent PS 126A, contact holes 302, and a bus bar 301. Each of pixel opening 124A is abutted by overhang structures 110, which define each of the sub-pixels 106 of the line-type architecture 200. The dot-type architecture 300 includes a plurality of pixel openings 124B from adjacent PS 126B. Each of pixel opening 124B is surrounded by overhang structures 110, which defines each of the sub-pixels 106 of the dot-type architecture 300.

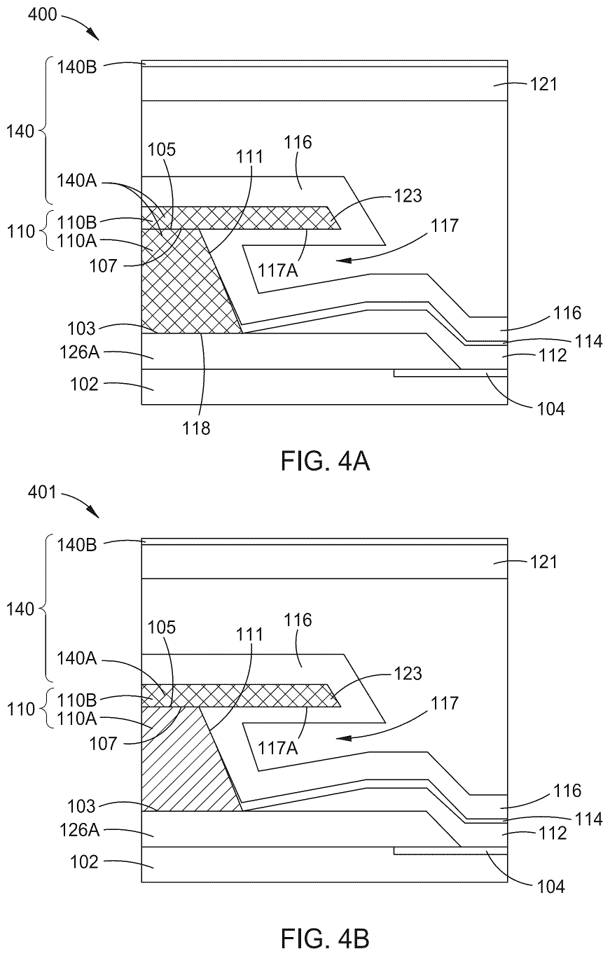

FIG. 4A is a schematic, cross-sectional view of an overhang structure 110 of the first sub-pixel circuit 100A having a third overhang structure configuration 400. However, it should be understood that the third overhang structure configuration 400 can be applied to the second sub-pixel circuit 100B. The third overhang structure configuration 400 includes overhang structures 110 that act as the first electrode. The first structure 110A and the second structure 110B include a conductive material. The conductive material may include a copper (Cu), aluminum (Al), aluminum neodymium (AlNd), molybdenum (Mo), molybdenum tungsten (MoW), titanium (Ti), transparent conductive oxide (TCO), or combinations thereof. In the example where the first structure 110A and the second structure 110B include a conductive material, the overhang structure 110, in entirety, is the touch-x axis electrode 140A. The OLED material 112 and the cathode 114 are disposed on the sidewall 111 of the first structure 110A. In one or more embodiments, an intermediate layer 121 is disposed over the second sub-pixel circuit 100B. The intermediate layer 121 covers the overhang structures 110. The intermediate layer 121 fills the sub-pixels 106. The intermediate layer 121 is disposed over the encapsulation layer 116. In one or more embodiments, the intermediate layer 121 is an ink jet layer. In one or more embodiments, the intermediate layer 121 is planarized. The global passivation layer 120 is disposed over the intermediate layer 121. In one or more embodiments, the global passivation layer 120 is disposed over the encapsulation layer 116.

The combination of the encapsulation layer 116, the intermediate layer 121, and the global passivation layer 120 provide a multilayer stack that provides a stable signal. In one or more embodiments, the intermediate layer 121 and the global passivation layer 120 are planarized to provide a flat surface for the deposition of the touch-y axis electrode 140B. The touch-y axis electrode 140B is disposed over the global passivation layer 120. The touch-y axis electrodes 140B include a TCO material such as ITO, a metal material (e.g., Cu or an Ag metal mesh), or nanowires (e.g., Ag nanowires or carbon (C) nanowires).

In one or more embodiments the third overhang structure configuration 400 includes an assistance cathode 142 as described below. In one or more embodiments, the third overhang structure configuration 400 includes a conductive body 146 as described below.

FIG. 4B is a schematic, cross-sectional view of an overhang structure 110 of the first sub-pixel circuit 100A having a fourth overhang structure configuration 401. However, it should be understood that the fourth overhang structure configuration 401 can be applied to the second sub-pixel circuit 100B. The fourth overhang structure configuration 401 includes overhang structures 110 where the second structure 110B acts as the touch-x axis electrode 140A. The first structure 110A includes a nonconductive material and the second structure 110B includes a conductive material. The nonconductive material includes amorphous silicon (a-Si), silicon nitride (Si₃N₄), silicon oxide (SiO₂), silicon oxynitride (Si₂N₂O), or combinations thereof. The conductive material may include a copper (Cu), aluminum (Al), aluminum neodymium (AlNd), molybdenum (Mo), molybdenum tungsten (MoW), titanium (Ti), transparent conductive oxide (TCO), or combinations thereof. In another embodiment, the first structure 110A includes a conductive material and the second structure 110B includes a nonconductive material. In the example where the first structure is a nonconductive material, the second structure 110B is the touch-x axis electrode 140A. The OLED material 112 and the cathode 114 are disposed on the sidewall 111 of the first structure 110A. In one or more embodiments, an intermediate layer 121 is disposed over the second sub-pixel circuit 100B. The intermediate layer 121 covers the overhang structures 110. The intermediate layer 121 fills the sub-pixels 106. The intermediate layer 121 is disposed over the encapsulation layer 116. In one or more embodiments, the intermediate layer 121 is an ink jet layer. In one or more embodiments, the intermediate layer 121 is planarized. The global passivation layer 120 is disposed over the intermediate layer 121. In one or more embodiments, the global passivation layer 120 is disposed over the encapsulation layer 116.

The combination of the encapsulation layer 116, the intermediate layer 121, and the global passivation layer 120 provide a multilayer stack that provides a stable signal. In one or more embodiments, the intermediate layer 121 and the global passivation layer 120 are planarized to provide a flat surface for the deposition of the touch-y axis electrode 140B. The touch-y axis electrode 140B is disposed over the global passivation layer 120. The touch-y axis electrodes 140B include a TCO material such as ITO, a metal material (e.g., Cu or an Ag metal mesh), or nanowires (e.g., Ag nanowires or carbon (C) nanowires).

In one or more embodiments the fourth overhang structure configuration 401 includes an assistance cathode 142 as described below. In one or more embodiments, the fourth overhang structure configuration 401 includes a conductive body 146 as described below.

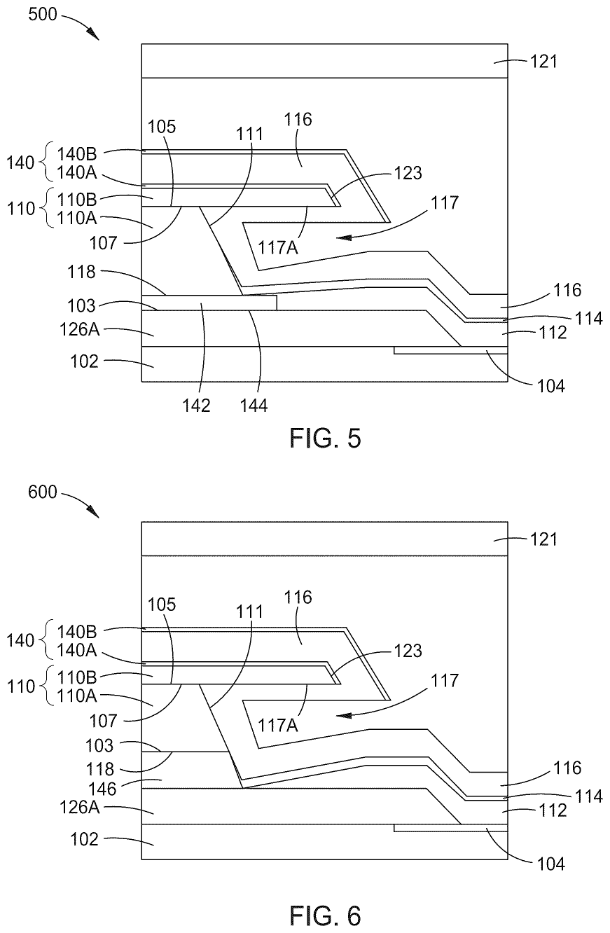

FIG. 5 is a schematic, cross-sectional view of an overhang structure 110 of the first sub-pixel circuit 100A having a fifth overhang configuration 500. However, it should be understood that the fifth overhang configuration 500 can be applied to the second sub-pixel circuit 100B. The fifth overhang configuration 500 includes an assistance cathode 142. The first structure 110A a nonconductive material. The nonconductive material includes amorphous silicon (a-Si), silicon nitride (Si₃N₄), silicon oxide (SiO₂), silicon oxynitride (Si₂N₂O), or combinations thereof. In another embodiment, the first structure 110A is a conductive material. The conductive material includes copper (Cu), aluminum (Al), aluminum neodymium (AlNd), molybdenum (Mo), molybdenum tungsten (MoW), titanium (Ti), transparent conductive oxide (TCO), or combinations thereof. The assistance cathode 142 is disposed over the substrate 102. In some embodiments, the assistance cathode 142 is disposed over the PS 126A. The overhang structure 110 is disposed over the assistance cathode 142. The assistance cathode 142 includes a protrusion 144 that extends at least past the width of the first structure 110A. In other embodiments, the protrusion 144 may extend past at least a bottom surface of the second structure 110B. The OLED material 112 and the cathode 114 may be disposed on the sidewall 111 of the first structure 110A. The cathode 114 contacts the assistance cathode 142. In some embodiments, the OLED material may contact the first structure 110A. The fifth overhang configuration 500 may be used in a dot-type architecture 300 or a line-type architecture 200.

FIG. 6 is a schematic, cross-sectional view of an overhang structure 110 of the first sub-pixel circuit 100A having a sixth overhang configuration 600. However, it should be understood that the sixth overhang configuration 600 can be applied to the second sub-pixel circuit 100B. The sixth overhang configuration 600 includes a conductive body 146. The first structure 110A is a nonconductive material. The nonconductive material include amorphous silicon (a-Si), titanium (Ti), silicon nitride (Si₃N₄), silicon oxide (SiO₂), silicon oxynitride (Si₂N₂O), or combinations thereof. The conductive body 146 is disposed over the substrate 102. In some embodiments, the conductive body 146 is disposed over the PS 126A. The overhang structure 110 is disposed over the conductive body 146. The conductive body 146 may include a transparent conductive oxide (TCO), copper (Cu), aluminum (Al), aluminum neodymium (AlNd), molybdenum (Mo), molybdenum tungsten (MoW), or combinations thereof. The OLED material 112 and the cathode 114 may be disposed on the sidewall 111 of the first structure 110A. The cathode 114 contacts the conductive body 146. In some embodiments, the OLED material may contact the first structure 110A. The sixth overhang configuration 600 may be used in a dot-type architecture 300 or a line-type architecture 200.

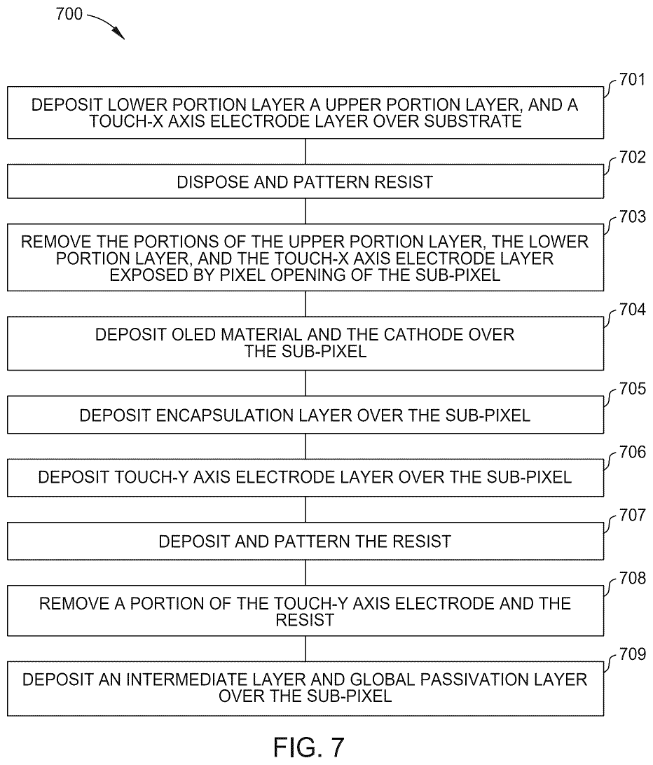

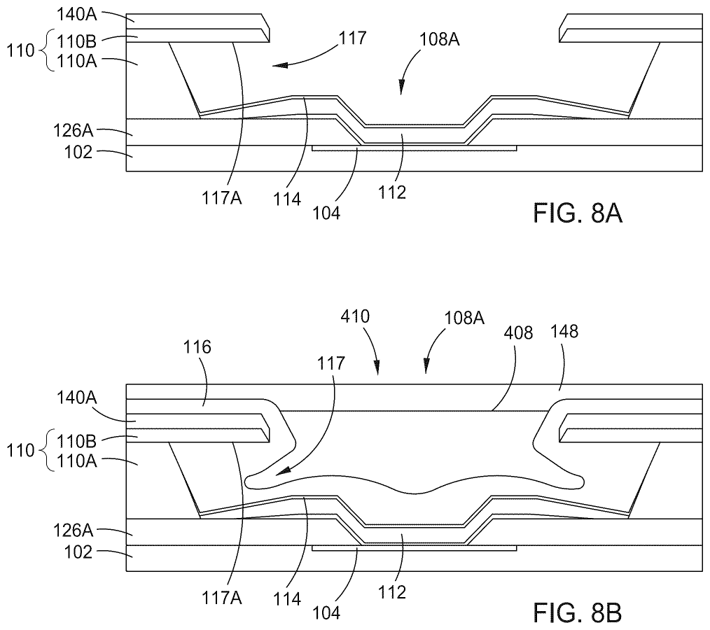

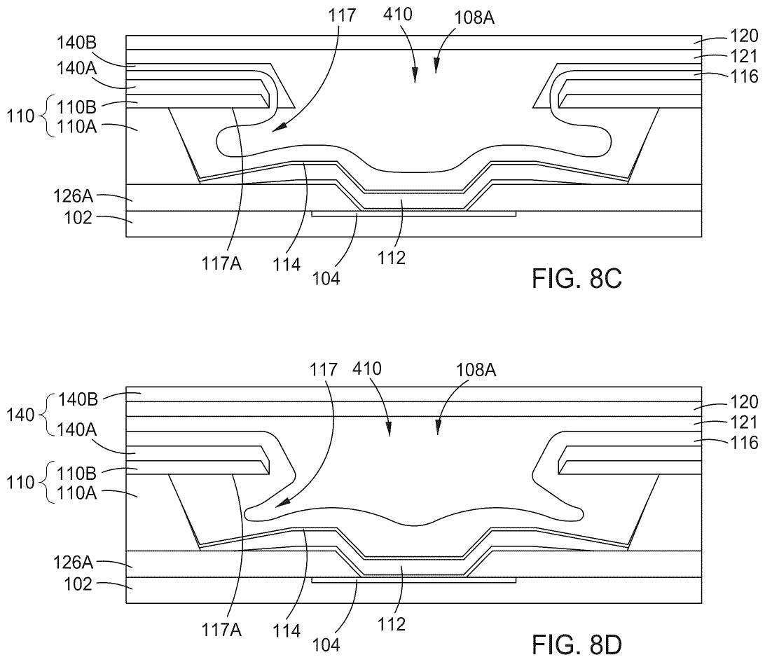

FIG. 7 is a flow diagram of a method 700 for forming sub-pixel (e.g., a first sub-pixel 108A). FIGS. 8A-8E are schematic, cross-sectional views of a substrate 102 during method 700 for forming a first sub-pixel 108A. The method 700 may be used to form the first sub-pixel circuit 100A or the second sub-pixel circuit 100B.

At operation 701, a lower portion layer, an upper portion layer, and a touch-x axis electrode layer are deposited over the substrate 102. The lower portion layer is disposed over the PS structures and the metal-containing layers. The upper portion layer is disposed over the lower portion layer. The lower portion layer corresponds to the first structure 110A and the upper portion layer corresponds to the second structure 110B of the overhang structures. In one or more embodiments, an assistant cathode layer is disposed between the lower portion layer and the PS structures. In one or more embodiments, including the conductive body 146, a conductive body layer is disposed between the lower portion layer and the PS structures. In one or more embodiments, the touch-x axis electrode layer is deposited over the upper portion layer.

In one or more embodiments, at operation 701, a lower portion layer and an upper portion layer are deposited over the substrate 102 (e.g., there is not a touch-x axis electrode layer deposited over the substrate). In this embodiment, at least the upper portion layer includes a conductive material. The conductive material may include a copper (Cu), aluminum (Al), aluminum neodymium (AlNd), molybdenum (Mo), molybdenum tungsten (MoW), titanium (Ti), transparent conductive oxide (TCO), or combinations thereof. The lower portion layer may include a conductive material or a nonconductive material. In the subsequent steps, the first sub-pixel 108A does not include the touch-x axis electrode 140A (as shown in FIG. 4A and 4B). In this embodiment, at least the second structure 110B (formed from the upper portion layer) acts as the touch-x axis electrode 140A.

At operation 702, a resist is disposed and patterned. The resist is disposed over the upper portion layer and/or the touch-x axis electrode layer. The resist is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the resist determines whether the resist is a positive resist or a negative resist. The resist is patterned to form one of a pixel opening of the dot-type architecture or a pixel opening of the line-type architecture of a first sub-pixel. The patterning is one of a photolithography, digital lithography process, or laser ablation process.

At operation 703, portions of the upper portion layer, the lower portion layer, and the touch-x axis electrode layer exposed by the pixel opening are removed. The upper portion layer exposed by the pixel opening may be removed by a dry etch process. This forms a sub-pixel. The lower portion layer exposed by the pixel opening may be removed by a wet etch process. In embodiments including the assistant cathode layer, a portion of the assistant cathode layer may be removed by a dry etch process or a wet etch process to form the assistant cathode 142 disposed under the first structure 110A. In embodiments including the conductive body 146, a portion of the conductive body layer may be removed by a dry etch process or a wet etch process to form the conductive body 146 disposed under the first structure 110A. In embodiments that include the touch-x axis electrode layer, a portion of the touch-x axis electrode layer is removed by a wet etch or a dry etch process. Operation 703 forms the overhang structures of the sub-pixel. The etch selectivity of the materials of the upper portion layer corresponding to the second structure and the lower portion layer corresponding to the first structure and the etch processes to remove the exposed portions of the upper portion layer and the lower portion layer provide for the bottom surface of the second structure being wider than the upper surface of the first structure to form the overhang. The shadowing of the overhang provides for evaporation deposition the OLED material and the cathode.

At operation 704, as show in FIG. 8A, the OLED material 112 of the first sub-pixel 108A and the cathode 114 are deposited. The shadowing of the overhang 117 provides for evaporation deposition each of the OLED material 112 and a cathode 114. At operation 705, as show in FIG. 8B, the encapsulation layer 116 is deposited over the first sub-pixel 108A. The encapsulation layer 116 contacts the touch-x axis electrode 140A. In certain embodiments, the encapsulation layer contacts the second structure 110B. E.g. the touch-X axis electrodes are not formed over the first sub-pixel 108A at operation 703.

In one or more embodiments, where the touch-x axis electrodes 140A are not formed over the first sub-pixel 108A at operation 703, a photoresist is patterned over the encapsulation layer 116. The encapsulation layer 116 is etched from the top surface of the second structure 110B. The touch-x axis electrodes are patterned over the overhang structures 110 (e.g., a touch-x axis electrode layer is deposited over the first sub-pixel 108A, a photoresist is patterned over the touch-x axis electrode layer, and a portion of the touch-x axis electrode layer is etched away, as described above). The encapsulation layer 116 is deposited over the touch-x axis electrodes.

At operation 706, as shown in FIG. 8B, a touch-y axis electrode layer 148 is deposited over the first sub-pixel 108A. The touch-y axis electrode layer 148 is at least disposed over the overhang structures 110. In one or more embodiments, a resist 408 is disposed in the first sub-pixel 108A before depositing the touch-y axis electrode layer 148. At operation 707 a resist is disposed and patterned over the touch-y axis electrode layer 148. The resist is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the resist determines whether the resist is a positive resist or a negative resist. The resist is patterned to form the touch-y axis electrodes 140B. The patterning is one of a photolithography, digital lithography process, or laser ablation process.

At operation 708, a portion of the touch-y axis electrode layer 148 and the resist is removed. For example, portions of the touch-y axis electrode layer 148 exposed by the resist are etched away. The portions of the touch-y axis electrode layer may be removed by a wet etch process or a dry etch process. In one or more embodiments, the touch-y axis electrodes 140B are formed over the overhang structures 110.

At operation 709, as shown in FIG. 8C, the intermediate layer 121 and the global passivation layer 120 are deposited over the first sub-pixel 108A. The intermediate layer 121 and the global passivation layer 120 are planarized.

In one or more embodiments, the intermediate layer 121 and the global passivation layer 120 are deposited before operation 706. For example, the encapsulation layer 116, the intermediate layer 121 and the global passivation layer 120 form a layer stack. In one or more embodiments the intermediate layer 121 and the global passivation layer 120 are one layer (e.g., the same layer). The intermediate layer 121 and the global passivation layer 120 are planarized such that the intermediate layer 121 and the global passivation layer 120 form a flat plane. As shown in FIG. 8D, the touch-y axis electrodes 140B are deposited over the global passivation layer 120. In one or more embodiments, the touch-y axis electrodes 140B are patterned over each of the overhang structures 110 (e.g., with a photoresist and an etch process as described above such that the touch-y axis electrodes 140B are not deposited over the well 410). In one or more embodiments, as shown in FIG. 8D, the touch-y axis electrodes 140B are formed as a layer across the first sub-pixel 108A.

In one embodiment, a device is disclosed. The device includes a substrate, a plurality of overhang structures disposed over the substrate where the overhang structures include a first structure, a second structure, and adjacent overhangs where each overhang defined by an overhang extension of the second structure extending laterally past an upper surface of the first structure. The device further includes a plurality of sub-pixels defined by the overhang structures where each sub-pixel includes an organic light emitting diode (OLED) material disposed between the overhang structures, a cathode disposed over the OLED material, and an encapsulation layer disposed over the cathode and the second structure over each of the overhang structures. The device further includes a first touch electrode disposed over the second structure and a second touch electrode disposed over the overhang structures.

In another embodiment, a device is disclosed. The device includes a substrate, a plurality of overhang structures disposed over the substrate where the overhang structures include a first structure, a second structure, and adjacent overhangs where each overhang defined by an overhang extension of the second structure extending laterally past an upper surface of the first structure. The device further includes a plurality of sub-pixels defined by the overhang structures where each sub-pixel includes an organic light emitting diode (OLED) material disposed between the overhang structures, a cathode disposed over the OLED material, and an encapsulation layer disposed over the cathode and the second structure over each of the overhang structures. The device further includes a first touch electrode disposed over the second structure, a second touch electrode disposed over the encapsulation layer that is over the second structure, and an assistance cathode where the first structure is disposed over the assistance cathode.

In another embodiment, a device is disclosed. The device includes a substrate, a plurality of overhang structures disposed over the substrate where the overhang structures include a first structure, a second structure, and adjacent overhangs where each overhang defined by an overhang extension of the second structure extending laterally past an upper surface of the first structure. The device further includes a plurality of sub-pixels defined by the overhang structures where each sub-pixel includes an organic light emitting diode (OLED) material disposed between the overhang structures, a cathode disposed over the OLED material, and an encapsulation layer disposed over the cathode and the second structure over each of the overhang structures. The device further includes a first touch electrode disposed over the second structure, a second touch electrode disposed over the encapsulation layer that is over the second structure, and conductive body where the first structure is disposed over the conductive body.

In another embodiment, a device is disclosed. The device includes a substrate, a plurality of overhang structures disposed over the substrate where the overhang structures include a first structure, a second structure, and adjacent overhangs where each overhang defined by an overhang extension of the second structure extending laterally past an upper surface of the first structure. The device further includes a plurality of sub-pixels defined by the overhang structures where each sub-pixel includes an organic light emitting diode (OLED) material disposed between the overhang structures, a cathode disposed over the OLED material, and an encapsulation layer disposed over the cathode and the second structure over each of the overhang structures. The device further includes a touch electrode disposed over the encapsulation layer that is over the second structure.

In yet another embodiment, a device is disclosed. The device includes a substrate, a plurality of overhang structures disposed over the substrate where the overhang structures include a first structure, a second structure, and adjacent overhangs where each overhang defined by an overhang extension of the second structure extending laterally past an upper surface of the first structure. The device further includes a plurality of sub-pixels defined by the overhang structures where each sub-pixel includes an organic light emitting diode (OLED) material disposed between the overhang structures, a cathode disposed over the OLED material, an encapsulation layer disposed over the cathode and the second structure over each of the overhang structures, and a global passivation layer. The device further includes a first touch electrode disposed over the second structure and a second touch electrode disposed over the global passivation layer that is disposed over the sub-pixels.

Overall, embodiments described herein generally relate to a display. More specifically, embodiments described herein relate to sub-pixel circuits and methods of forming sub-pixel circuits that may be utilized in a display such as an organic light-emitting diode (OLED) display. Embodiments disclosed herein further include a sub-pixel circuit with touch-x axis electrodes and touch-y axis electrodes to form a touch screen panel. The touch electrodes are integrated into the OLED architecture, providing a thin device that improves flexibility, reliability, and performance of the overall device. The integration of the electrodes into the OLED architecture allows for the omission of additional structures to provide the touch screen panel capabilities.

While the foregoing is directed to embodiments of the present disclosure, other and further embodiments of the disclosure may be devised without departing from the basic scope thereof, and the scope thereof is determined by the claims that follow.

What is claimed is:

1. A device, comprising:
a substrate;
a plurality of overhang structures disposed over the substrate, each overhang structure of the plurality of overhang structures comprising:
a first structure;
a second structure; and
adjacent overhangs, each overhang of the adjacent overhangs defined by an overhang extension of the second structure extending laterally past an upper surface of the first structure;
a first touch electrode disposed over the second structure;
a plurality of sub-pixels defined by the plurality of overhang structures, each sub-pixel comprising:
an organic light emitting diode (OLED) material disposed between the overhang structures;
a cathode disposed over the OLED material; and
an encapsulation layer disposed over the cathode and at least the second structure of each overhang structure of the plurality of overhang structures;
an intermediate layer disposed over the encapsulation layer; and
a second touch electrode disposed over the intermediate layer.

2. The device of claim 1, wherein the cathode has an endpoint before the first structure.

3. The device of claim 1, wherein the second structure and the first structure are comprised of a conductive material.

4. The device of claim 3, wherein the conductive material includes one or more of a transparent conductive oxide (TCO), copper (Cu), aluminum (Al), aluminum neodymium (AlNd), molybdenum (Mo), molybdenum tungsten (MoW), titanium (Ti), or combinations thereof.

5. The device of claim 1, wherein the encapsulation layer comprises a dielectric material.

6. The device of claim 1, wherein the first structure is comprised of a nonconductive material and the second structure is comprised of a conductive material.

7. The device of claim 6, wherein the nonconductive material includes amorphous silicon (a-Si), silicon nitride (Si₃N₄), silicon oxide (SiO₂), silicon oxynitride (Si₂N₂O), or combinations thereof and the conductive material includes the conductive material includes a transparent conductive oxide, copper (Cu), aluminum (Al), aluminum neodymium (AlNd), molybdenum (Mo), molybdenum tungsten (MoW), titanium (Ti), or combinations thereof.

8. The device of claim 1, wherein the device further comprises a global passivation layer disposed over the intermediate layer.

9. The device of claim 1, wherein the intermediate layer is planarized.

10. The device of claim 1, wherein the first touch electrode and the second touch electrode comprise a transparent conductive oxide (TCO), a metal-containing layer, a metal, or combinations thereof.

11. A device, comprising:
a substrate;
a plurality of overhang structures disposed over the substrate, each overhang structure of the plurality of overhang structures comprising:
a first structure;
a second structure; and
adjacent overhangs, each overhang of the adjacent overhangs defined by an overhang extension of the second structure extending laterally past an upper surface of the first structure;
a first touch electrode disposed over the second structure;
a plurality of sub-pixels defined by the plurality of overhang structures, each sub-pixel comprising:
an organic light emitting diode (OLED) material disposed between the overhang structures;
a cathode disposed over the OLED material; and
an encapsulation layer disposed over the cathode and at least the second structure of each overhang structure of the plurality of overhang structures;
an intermediate layer disposed over the encapsulation layer;
a global passivation layer disposed over the intermediate layer; and
a second touch electrode disposed over the global passivation layer.

12. The device of claim 11, further comprising an assistance cathode disposed under each overhang structure of the plurality of overhang structures.

13. The device of claim 12, wherein the assistance cathode includes a protrusion, the protrusion extending at least past the first structure.

14. The device of claim 12, wherein the assistance cathode comprises a transparent conductive oxide (TCO), a copper (Cu), aluminum (Al), aluminum neodymium (AlNd), molybdenum (Mo), molybdenum tungsten (MoW), titanium (Ti), or combinations thereof.

15. The device of claim 12, wherein the cathode contacts the assistance cathode.

16. The device of claim 11, wherein the encapsulation layer is a dielectric layer.

17. A device, comprising:
a substrate;
a plurality of overhang structures disposed over the substrate, each overhang structure of the plurality of overhang structures comprising:
a first structure;
a second structure comprising a conductive material; and
adjacent overhangs, each overhang of the adjacent overhangs defined by an overhang extension of the second structure extending laterally past an upper surface of the first structure;
a plurality of sub-pixels defined by the plurality of overhang structures, each sub-pixel comprising:
an organic light emitting diode (OLED) material disposed between the overhang structures;
a cathode disposed over the OLED material; and
an encapsulation layer disposed over the cathode and at least the second structure of each overhang structure of the plurality of overhang structures;
an intermediate layer disposed over the encapsulation layer;
a global passivation layer disposed over the intermediate layer; and
a touch electrode disposed over the global passivation layer that is over the second structure.

18. The device of claim 17, wherein the encapsulation layer is a dielectric layer.

19. The device of claim 17, further comprising a conductive body disposed under each overhang structure of the plurality of overhang structures.

20. The device of claim 17, wherein the touch electrode comprises a transparent conductive oxide (TCO), a metal-containing layer, a metal, or combinations thereof.
